(19) United States
(12) Patent Application Publication
(10) Pub. No.: US 2008/0137276 A1
(43) Pub. Date: Jun. 12, 2008

(54) DISPLAY DEVICE

(75) Inventor: Hirohide OKAHARA, Kanagawa (JP)

Correspondence Address: RATNERPRESTIA, P.O. BOX 980, VALLEY FORGE, PA, 19482, US

(73) Assignee: MATSUSHITA ELECTRIC INDUSTRIAL CO., LTD., Osaka (JP)

(21) Appl. No.: 12/025,861

(22) Filed: Feb. 5, 2008

Related U.S. Application Data
(63) Continuation of application No. 11/297,071, filed on Dec. 8, 2005.

(30) Foreign Application Priority Data
Dec. 13, 2004 (JP) JP 2004-359793

(51) Int. Cl. H05K 7/16

(52) U.S. Cl. 361/681; 248/324

(57) ABSTRACT

A display is rotatably supported by a hinge portion as a support portion. The hinge portion has an engaging portion for performing engagement when the display is rotated to a predetermined using position. The engaging portion is constructed so as to perform the engagement in plural engaging places when the display is rotated to the predetermined using position. The engaging portion has a fixing member and a rotating member constituting the hinge portion. One of the fixing member and the rotating member has plural convex portions, and the other has plural concave portions. These plural convex portions and concave portions are arranged so as to be engaged with each other. Thus, durability of the engaging portion is improved, and GND ability can be improved.

This application is a continuation of U.S. patent application Ser. No. 11/297,071, filed Dec. 8, 2005, the entire disclosure of which is incorporated herein by reference.

### BACKGROUND OF THE INVENTION

1. Field of the Invention

The present invention relates to a display device for rotatably supporting a display.

2. Background

There is conventionally a case in which the display is rotatably arranged in a vehicle, etc. For example, the display device of this kind is disclosed in JP-A-2-86277 (page 2 and FIG. 2). In this literature, hinges are arranged on both sides of the display.

In the above literature, the position of the display is steplessly adjusted. The display device of another type different from such a stepless adjusting type is locked in a predetermined using position. The display device of this type is shown in FIGS. 11 to 13.

In FIG. 11, the display 100 is supported by hinges 102, 104 on both the sides. FIG. 12 typically shows the hinge 102. The hinge 102 has an engaging means. The engaging means is constructed by a bracket 106 and a rotating spring 108. The bracket 106 is fixed and rotatably supports a hinge shaft. The rotating spring 108 is arranged so as to be rotated together with the hinge shaft. One concave portion 110 is arranged in the bracket 106, and one convex portion 112 is arranged in the rotating spring 108. When the display 100 is rotated and reaches a predetermined using position, the convex portion 112 reaches the concave portion 110. As shown in FIG. 13, the convex portion 112 and the concave portion 110 are then engaged with each other. Thus, the position of the display 100 is locked. As shown by a dotted line in the cross-sectional view of FIG. 13, when the convex portion 112 and the concave portion 110 are shifted, the convex portion 112 is interposed between the bracket 106 and the rotating spring 108. Accordingly, the rotating spring 108 is elastically deformed and warped. Thus, the convex portion 112 is pushed against the bracket 106 by spring pressure.

As mentioned above, the display device conventionally has the engaging means constructed by a combination of one concave portion and one convex portion. Such an engaging means is arranged in the hinge on one side of the display. Otherwise, the engaging means of a similar construction is arranged in the hinges on both the sides of the display.

However, as shown by the dotted line in the cross-sectional view of FIG. 13, in the conventional display device, the convex portion is pressed against the bracket by the spring pressure except for an engaging place, and is slid. Therefore, when the number of using times is increased, wearing of the convex portion is caused and there is a tendency in which holding force of the engaging portion is reduced.

Further, in the conventional display device, there are many cases in which the housing of the device is utilized for a electric GND (grounding) and a GND level is set to the housing of the device. However, in the construction for obtaining contact between metals by the engaging portion (concave and convex), there is a case in which the impedance of the engaging portion is raised since the contact is insufficient. In this case, GND force is reduced (the GND level becomes unstable). Furthermore, the spring force is reduced in accordance with a use with the passage of time and the contact pressure of the engaging portion is reduced. There is a tendency in which the GND force is further reduced. Thus, in the conventional display device, there was room for an improvement of electric performance with respect to GND.

### SUMMARY OF THE INVENTION

The present invention is made under the above background. An purpose of the present invention is to provide a display device able to improve durability of the engaging structure and also improve the electric performance.

A display device of the present invention comprises a display, a support portion for rotatably supporting the display, and at least one engaging portion for performing engagement when the display is rotated to a predetermined using position, the engaging portion being constructed so as to perform the engagement in plural engaging places when the display is rotated to the predetermined using position.

As described hereafter, other aspects of the invention exist. Thus, this summary of the invention is intended to provide a few aspects of the invention and is not intended to limit the scope of the invention described and claimed herein.

### BRIEF DESCRIPTION OF THE DRAWINGS

The accompanying drawings are incorporated in and constitute a part of this specification. The drawings exemplify certain aspects of the invention and, together with the description, serve to explain some principles of the invention.

FIG. 1 is an exploded perspective view of a display device in an embodiment of the present invention.

FIG. 2 is an exploded perspective view of a right-hand hinge portion.

FIG. 3 is an exploded perspective view of a left-hand hinge portion.

FIG. 4 is a perspective view showing the display device in a closing state.

FIG. 5 is a perspective view showing the display device in a semi-opening state.

FIG. 6 is a perspective view showing the display device in a full opening state.

FIG. 7 is a view showing a modified example of the hinge portion.

FIG. 8 is a view showing a modified example of the hinge portion.

FIG. 9 is a view showing a modified example of the hinge portion.

FIG. 10 is a view showing a modified example of the hinge portion.

FIG. 11 is a view showing a conventional display device.

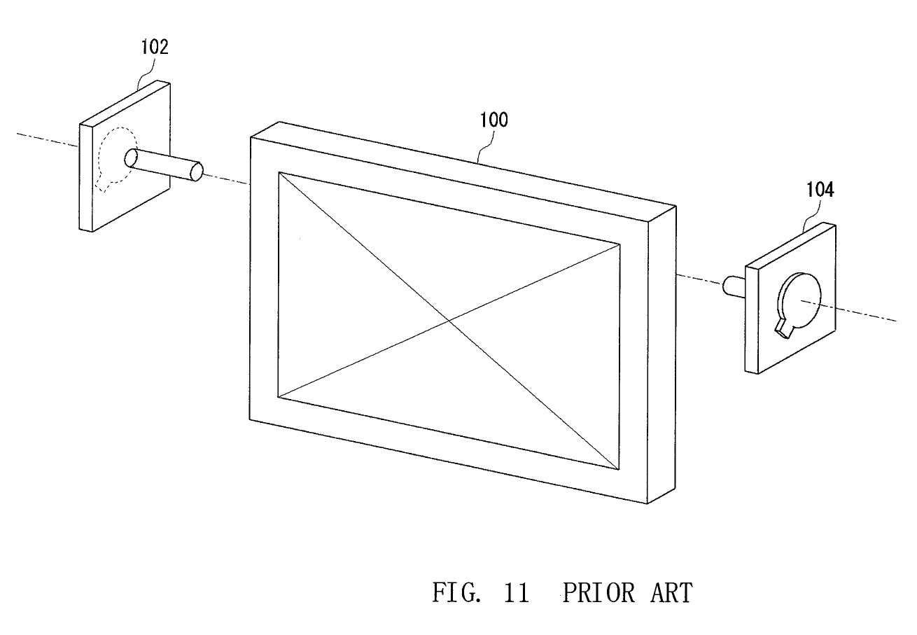

FIG. 12 is a view showing the conventional display device.

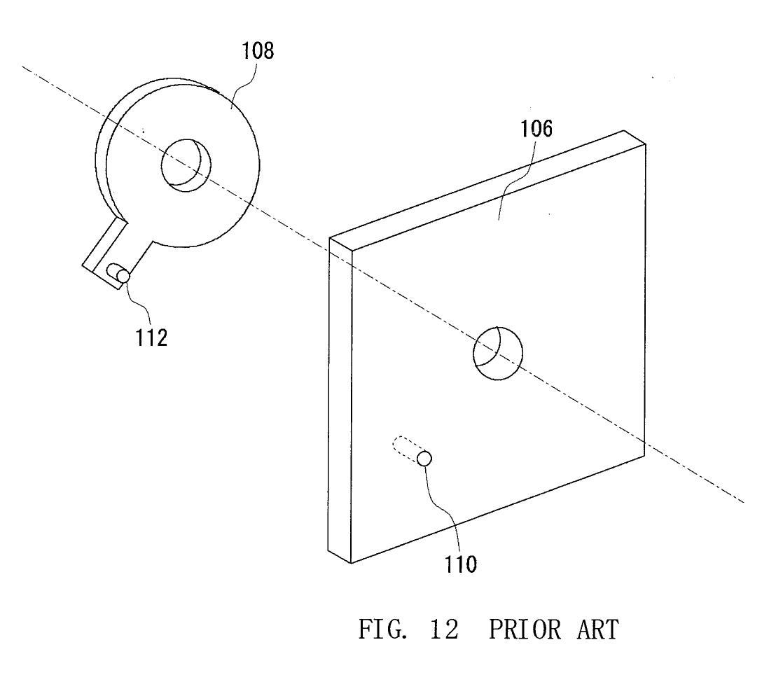

FIG. 13 is a view showing the conventional display device.

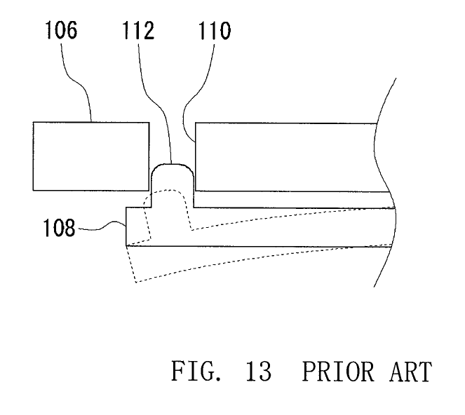

### DESCRIPTION OF THE PREFERRED EMBODIMENTS

The following detailed description refers to the accompanying drawings. Although the description includes exemplary implementations, other implementations are possible and changes may be made to the implementations described without departing from the spirit and scope of the invention. The following detailed description and the accompanying drawings do not limit the invention. Instead, the scope of the invention is defined by the appended claims.

This display device comprises a display, a support portion for rotatably supporting the display, and at least one engaging portion for performing engagement when the display is rotated to a predetermined using position, the engaging portion being constructed so as to perform the engagement in plural engaging places when the display is rotated to the predetermined using position. The above engaging portion may be arranged at one end of the display, and may be also arranged at both ends of the display.

In this construction, the engaging portion or an engaging means is constructed so as to perform the engagement in the plural engaging places when the display is rotated until the using position. Accordingly, in this construction, load to the engaging place for obtaining the same holding force can be reduced, and the load in the engaging place can be reduced, and durability of the engaging portion can be improved. Further, in this construction, GND force is improved by increasing the engaging places, and electric performance can be improved.

Further, the engaging portion may have a fixing member and a rotating member rotated in accordance with the rotation of the display, and one of the fixing member and the rotating member may have plural convex portions, and the other may have plural concave portions, and the plural convex portions and the plural concave portions may be arranged so as to be engaged with each other. Since the plural convex portions are arranged, this construction can reduce the load to the convex portion and can reduce wearing of the convex portion and can improve durability of the engaging portion.

Further, the plural concave portions arranged so as to be separated in the circumferential direction may be provided corresponding to each of the convex portions in the engaging portion. The display can be used by this construction in plural using positions.

Further, the positions of the plural convex portions in the engaging portion may be set to positions in which the distances from the center of rotation of the rotating member are different from each other. In this construction, a construction able to use the display in the plural using positions can be provided in a small space.

A ceiling mounting type display device is provided in another aspect. The ceiling mounting type display device has the above display device, and may be constructed so as to be mounted to a ceiling. This construction can improve durability of the engaging portion and can also improve electric performance with respect to GND in the ceiling mounting type display device of a vehicle, etc.

The display device of this embodiment will next be explained by using the drawings.

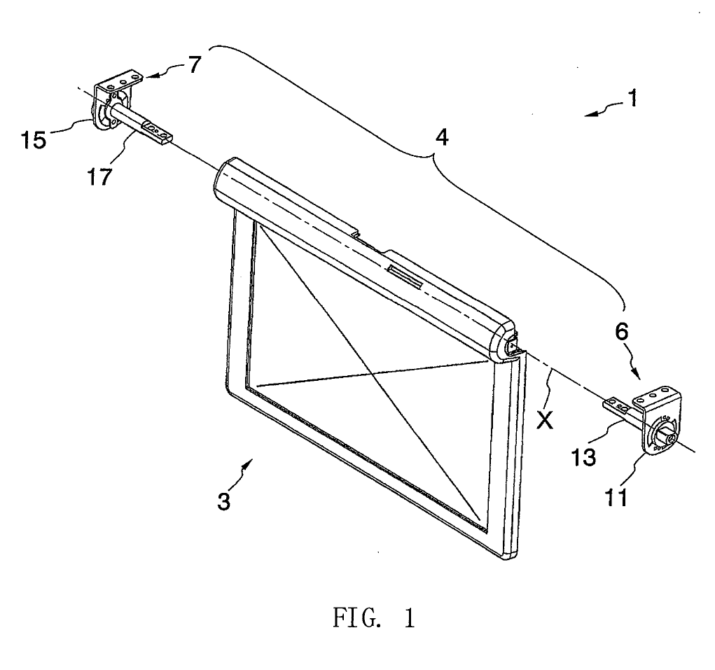

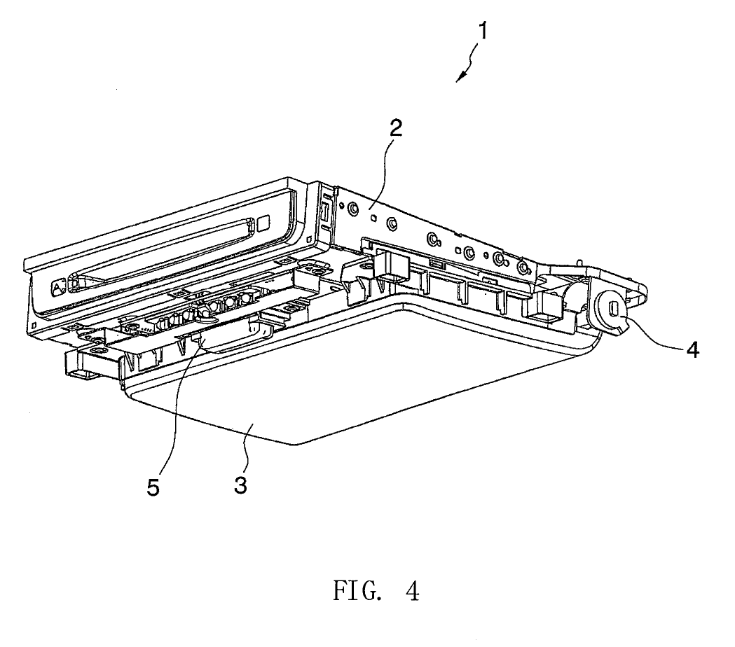

The display device of this embodiment is shown in FIGS. 1 to 6. First, the entire construction of the display device will be explained with reference to FIGS. 4 to 6. It is then returned to FIG. 1 and the details of the construction of the display device will be explained.

FIGS. 4 to 6 show the entire construction of the display device of this embodiment. The display device 1 has a base portion 2 and a display 3. The display 3 is a planar display of liquid crystal, etc., and is rotatably supported to the base portion 2 by a hinge portion 4. The hinge portion 4 corresponds to a support portion of the present invention.

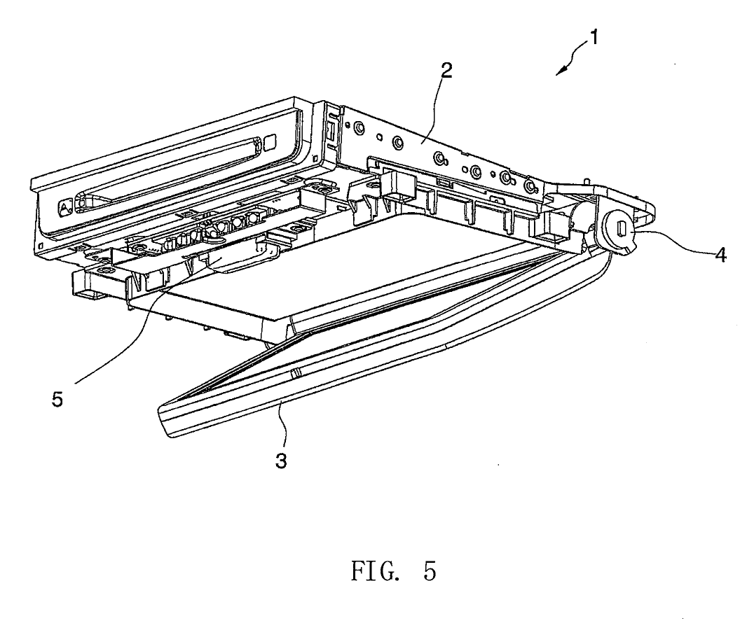

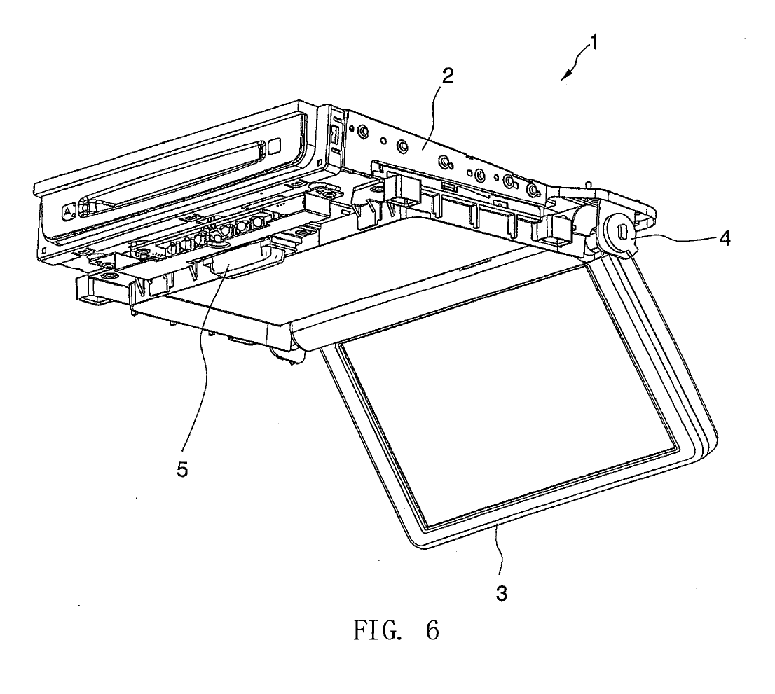

The display device 1 of this embodiment is used for a vehicle, and is arranged in the ceiling of a vehicle room in postures shown in FIGS. 4 to 6. In an arranging state, a mechanical portion of the base portion 2 is hidden by the lining of the ceiling. FIG. 4 shows a full closing state and FIG. 5 shows a semi-opening state and FIG. 6 shows a full opening state. In the full closing state of FIG. 4, the screen of the display 3 is directed to the ceiling, and the display is located in a storing position. When a release button 5 arranged in the display 3 is pushed, a lock is released and the display 3 can be rotated and opened as shown in FIGS. 5 and 6.

FIG. 1 is an exploded perspective view of the display device 1, and shows the display 3 and the hinge portion 4. The hinge portion 4 is constructed by a right-hand hinge portion 6 and a left-hand hinge portion 7. The right-hand hinge portion 6 and the left-hand hinge portion 7 are respectively arranged on the right-hand side and the left-hand side of the display 3.

The right-hand hinge portion 6 has a right-hand bracket 11 fixed to the base portion 2, and a right-hand shaft 13 rotatably arranged in the right-hand bracket 11. The right-hand shaft 13 is fixed to a base end portion of the display 3. Similarly, the left-hand hinge portion 7 has a left-hand bracket 15 fixed to the base portion 2, and a left-hand shaft 17 rotatably arranged in the left-hand bracket 15. The left-hand shaft 17 is fixed to a base end portion of the display 3.

Here, in the following explanation, the side close to the center of the display 3 along a rotating axis X is called the inside, and the side far from the center of the display 3 is called the outside.

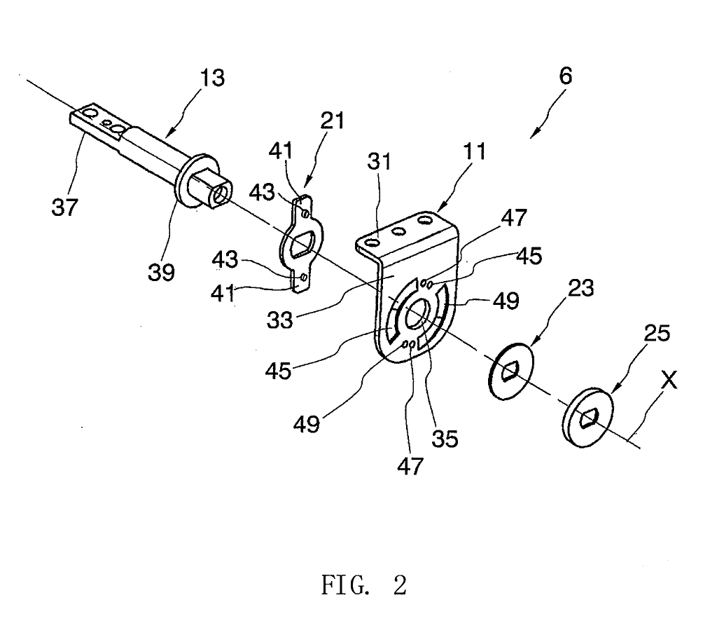

FIG. 2 is an exploded perspective view of the right-hand hinge portion 6. The right-hand hinge portion 6 has the right-hand bracket 11, the right-hand shaft 13, a click washer 21, a spring plate 23 and a flat washer 25 and these members are manufactured from iron.

The right-hand bracket 11 has an attaching portion 31 fixed to the unillustrated base portion, and a wall portion 33 perpendicular to the attaching portion 31. The right-hand shaft 13 is inserted into a hole 35 of the wall portion 33. Thus, the right-hand shaft 13 is rotatably supported. The hole 35 of the wall portion 33 functions as a bearing of the right-hand shaft 13.

The right-hand shaft 13 is fixed to the display 3 by an attaching portion 37 at the inside end. A flange 39 is arranged near an outside end of the right-hand shaft 13. In a state in which the right-hand shaft 13 is inserted into the hole 35 of the right-hand bracket 11, the click washer 21 is nipped by the flange 39 and the wall portion 33 of the bracket 11.

The click washer 21 has a disk shape, and the right-hand shaft 13 is inserted into a central hole of the click washer 21. The central hole of the click washer 21 has a shape engaged with the right-hand shaft 13. More specifically, two parallel straight line portions are arranged in the central hole. These straight line portions are engaged with two parallel planes of an end portion of the right-hand shaft 13. Thus, the click washer 21 is engaged with the right-hand shaft 13, and is rotated together with the right-hand shaft 13. The click washer 21 is slid with respect to the right-hand bracket 11.

An outside end portion of the right-hand shaft 13 extends through the right-hand bracket 11 and is projected out. The spring plate 23 and the flat washer 25 are sequentially fitted to the projecting-out portion. The spring plate 23 and the flat washer 25 have a disk shape. Similar to the click washer 21, the right-hand shaft 13 is inserted and engaged with central holes of the spring plate 23 and the flat washer 25. Thus, the spring plate 23 and the flat washer 25 are also rotated together with the right-hand shaft 13. The flat washer 25 maintains the axial position relation between constructions of the right-hand hinge portion 6. The right-hand bracket 11, the right-hand shaft 13 and the click washer 21 are mutually pressed by the spring plate 23.

The construction of the engaging portion or the engaging means in this embodiment will next be explained. The click washer 21 has two arm portions 41 extended in a radial shape. The two arm portions 41 are located on the opposite side with a hinge axis X as a center. A convex portion 43 is arranged in each arm portion 41 so as to be directed to the right-hand bracket 11.

On the other hand, two concave portions 45, 47 are arranged in positions corresponding to each convex portion 43 in the wall portion 33 of the right-hand bracket 11. The concave portions 45, 47 are constructed by through holes. In the concave portions 45, 47 and the convex portion 43, the distances from the rotating axis X are set to the same. The two concave portions 45, 47 are arranged correspondingly to each of the two convex portions 43. Accordingly, the total number of concave portions is 4. The concave portions 45, 47 are located in positions shifted on the circumference of a circle with the rotating axis X as a center.

The concave portions 45, 47 correspond to two using positions set in the display device 1 of this embodiment. When the display 3 is located in a first using position, the convex portions 43 face the first concave portions 45. When the display 3 is located in a second using position, the convex portions 43 face the second concave portions 47.

When the convex portions 43 are located in positions shifted from the concave portions 45 and the concave portions 47, the convex portions 43 are interposed between the click washer 21 and the right-hand bracket 11. Therefore, the arm portions 41 of the click washer 21 are flexed and deformed. When the convex portions 43 reach the concave portions 45 or the concave portions 47, the deformation of the arm portions 41 are restored and the convex portions 43 are fitted into the concave portions 45 or the concave portions 47 so that an engaging state is obtained.

Further, arc convex portions 49 are arranged in positions shifted from the concave portions 45, 47 in the click washer 21. The arc convex portions 49 are extended along a path through which the convex portions 43 of the click washer 21 passes. Each arc convex portion 49 is constructed by a flat portion and a taper portion (slope portion). In the arc convex portions 49, the convex portions 43 of the click washer 21 are pushed up or lifted. Thus, the click washer 21 is deformed and biases the right-hand bracket 11. This deformation increases torque resisting the rotating movement of the display 3. The shape of the arc convex portions 49 are set so as to generate torque for giving a moderate resisting feeling (responsive feeling) to an operator at an operating time.

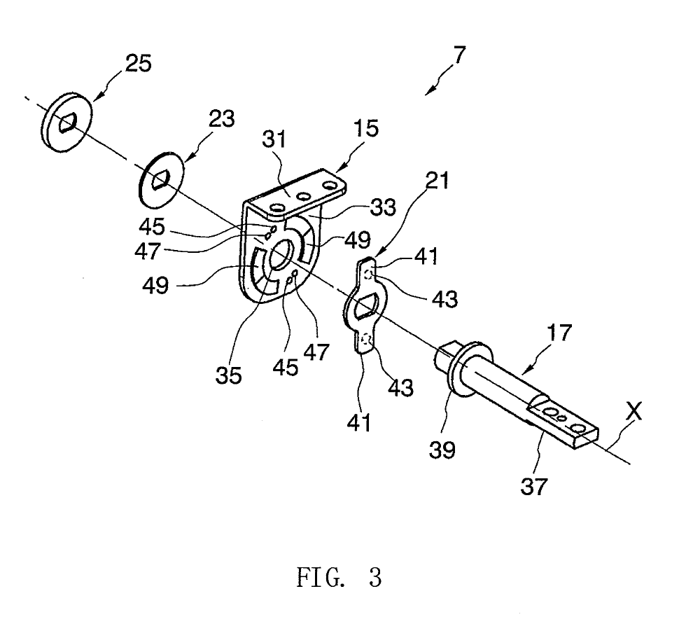

FIG. 3 is an exploded perspective view of the left-hand hinge portion 7. The left-hand hinge portion 7 has the left-hand bracket 15, the left-hand shaft 17, the click washer 21, the spring plate 23 and the flat washer 25. Similar to the right-hand hinge portion 6, the left-hand shaft 17 is also inserted into the left-hand bracket 15 in the left-hand hinge portion 7. The click washer 21 is nipped between the left-hand bracket 15 and the left-hand shaft 17. The spring plate 23 and the flat washer 25 are fitted to the left-hand shaft 17 on the opposite side of the left-hand bracket 15. Similar to the right-hand hinge portion 6, the convex portions 43 are also arranged in the arm portions 41 of the click washer 21 in the left-hand hinge portion 7, and the concave portions 45, 47 are arranged in the left-hand bracket 15. These portions constitute the engaging portion. The construction of the left-hand hinge portion 7 is similar to the construction of the right-hand hinge portion 6, and its detailed explanation is therefore omitted.

The construction of the display device 1 of this embodiment has been explained as mentioned above. Next, the operation of the display device 1 of this embodiment will be explained.

First, the operation of the display device 1 at an opening time of the display 3 will be explained. When a button 5 (FIG. 4) of the display device 1 is pushed, the lock of the display 3 is released and the display 3 can be rotated with the rotating axis of the hinge portion 4 as a center. The tip of the display 3 is lowered downward to a certain extent by the weight of the display 3. The tip of the display 3 is manually pushed down by a user, and the display 3 is further rotated (FIGS. 5 and 6).

At this time, in the right-hand hinge portion 6, the click washer 21 is rotated together with the right-hand shaft 13. The click washer 21 is rotated with respect to the right-hand bracket 11. When the display 3 reaches the first using position, the two convex portions 43 of the click washer 21 simultaneously reach the two concave portions 45 of the right-hand bracket 11, and are fitted and engaged with the two concave portions 45. Similarly, in the left-hand hinge portion 7, the click washer 21 is rotated with respect to the left-hand bracket 15. When the display 3 reaches the first using position, the two convex portions 43 of the click washer 21 simultaneously reach the two concave portions 45 of the left-hand bracket 15, and are fitted and engaged with the two concave portions 45. Thus, the display 3 is locked in the first using position.

When the tip of the display 3 is further pushed by a user, the display 3 is further rotated. At this time, in the right-hand hinge portion 6 and the left-hand hinge portion 7, the convex portions 43 of the click washer 21 are disengaged from the concave portions 45, and the click washer 21 is further rotated. When the display 3 reaches the second using position, the convex portions 43 of the click washer 21 reach the concave portions 47. In each of the right-hand hinge portion 6 and the left-hand hinge portion 7, the two convex portions 43 are simultaneously fitted and engaged with the two concave portions 47. Thus, the display 3 is locked in the second using position.

Next, the operation of the display device 1 at a closing time of the display 3 will be explained. When the display 3 is closed, the display 3 is pushed by a hand of the user and is rotated. At this time, in the right-hand hinge portion 6 and the left-hand hinge portion 7, the convex portions 43 of the click washer 21 are disengaged from the concave portions 47, and the lock state is released. When the display 3 is rotated, the convex portions 43 of the click washer 21 are fitted and engaged with the concave portions 45 of the bracket. When the display 3 is further pushed, the convex portions 43 of the click washer 21 are disengaged from the concave portions 45, and the display 3 is rotated and reaches a storing position. When the display 3 reaches the storing position, the lock is automatically operated and the display 3 is locked in the storing position.

Here, in this embodiment, the engaging portion is arranged in each of the right-hand hinge portion 6 and the left-hand hinge portion 7. In each engaging portion, two engaging places opposed by 180 degrees are arranged. (In this embodiment, there are two sets of “two engaging places”. A first set is a pair of two concave portions 45. A second set is a pair of two concave portions 47.) Thus, in this embodiment, the two engaging places are arranged. On the other hand, in the prior art, the number of engaging places is one. Accordingly, when this embodiment is compared with the prior art, spring force to be given to the click washer 21 in order to obtain the same holding force can be set to half in this embodiment. Accordingly, in this embodiment, load applied to each engaging place at the hinge rotating time can be set to half. In the above example, when the convex portions 43 are pressed against the bracket wall portion 33 in a non-engaging state, the pressing force becomes half. Thus, wearing of the engaging place can be reduced and a reduction in the holding force caused by the wearing can be prevented.

The above construction will be explained in further detail. When the number of engaging places is one, it is assumed that the magnitude of load is a wearing generating level or more. In this case, the load of each engaging place can be set less than wearing generating level (critical value) by setting the number of engaging places to two in this embodiment. Thus, the generation of the wearing can be substantially removed. Accordingly, durability of the holding force can be set to twice or more by increasing the number of engaging places to two. Thus, reliability of twice or more can be secured.

Further, in the above embodiment, the number of contact places between metals of the display and GND becomes two and GND points are increased by setting the number of engaging places to two. Thus, the GND force is increased and electric performance with respect to GND is improved.

Further, in this embodiment, two concave portions are arranged correspondingly to one convex portion. However, three concave portions or more may be also arranged with respect to one convex portion. Conversely, one concave portion may be also arranged with respect to one convex portion.

Further, in this embodiment, the engaging portions are arranged in the two hinge portions. However, the engaging portion may be also arranged in only one hinge portion.

Further, in this embodiment, the convex portions are arranged in the click washer as a rotating member, and the concave portions are arranged in the bracket as a fixing member. In contrast to this, the convex portions may be arranged in the fixing member, and the concave portions may be arranged in the rotating member.

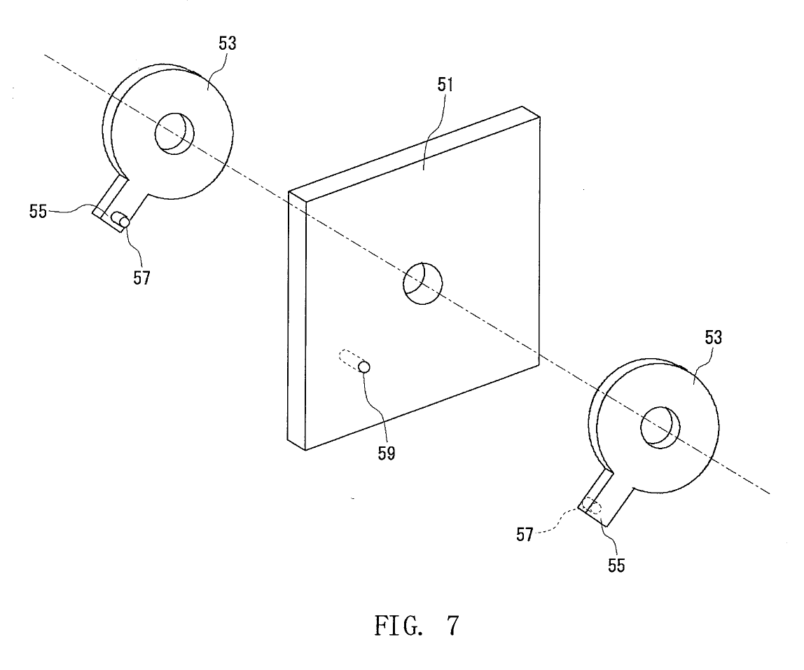

Next, other modified examples of the above embodiment will be explained with reference to FIGS. 7 to 10. The bracket and the click washer are typically shown in FIGS. 7 to 10.

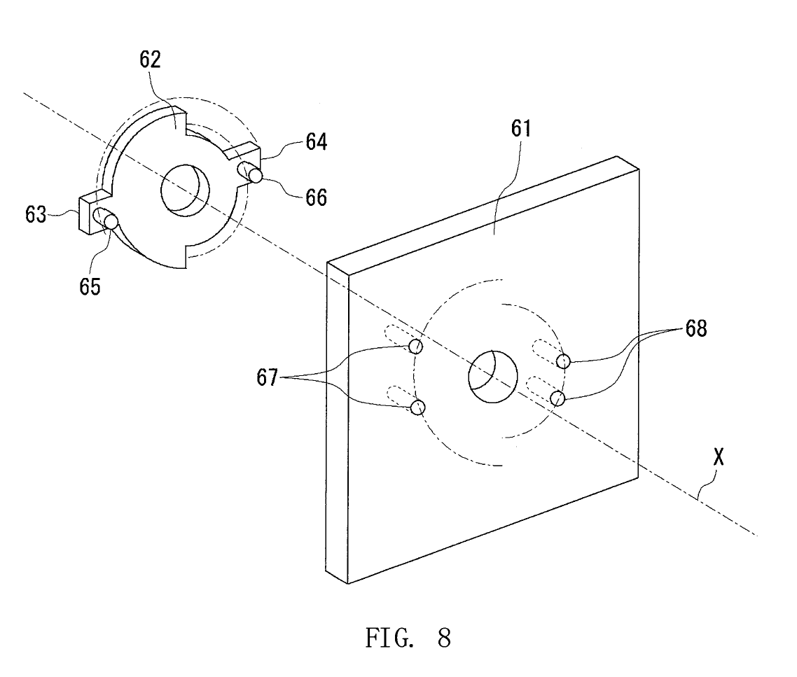

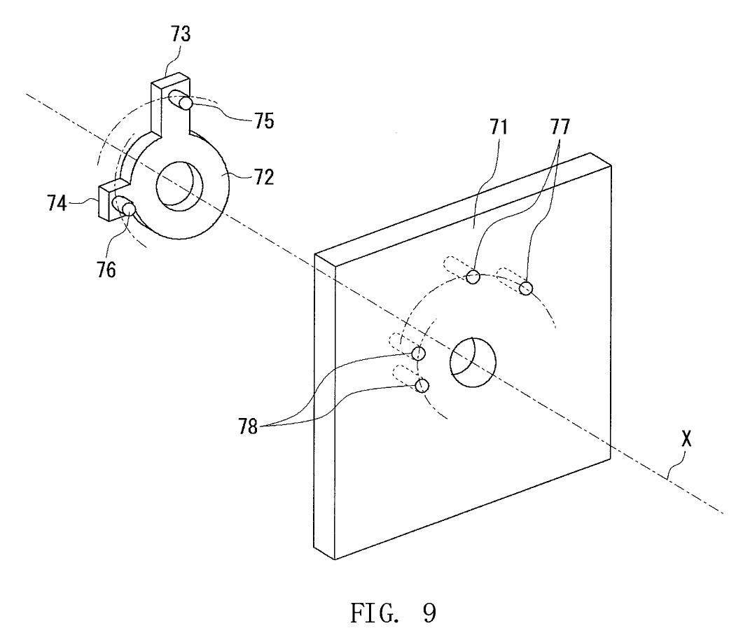

In FIG. 7, click washers 53 are arranged on both sides of the bracket 51. Each click washer 53 has one arm portion 55. A convex portion 57 is arranged in the arm portion 55. The two click washers 53 are rotated together with the display. When the display reaches a using position, the two convex portions 57 are fitted and engaged with the concave portion 59 from both the sides of the bracket 51. The construction of FIG. 7 may be arranged in the hinge portions on both sides of the display, and may be also arranged in the hinge portion on one side (this is similarly adopted in FIGS. 8 and 9).

Next, FIG. 8 shows a bracket 61 and a click washer 62. In FIG. 8, the click washer 62 is constructed by two semi-disks of different radii. Arm portions 63, 64 are arranged in the respective semi-disks, and convex portions 65, 66 are arranged in the arm portions 63, 64. Accordingly, in the two convex portions 65, 66, the distances from the rotating axis X are different from each other. In accordance with this difference, concave portions 67, 68 are also arranged in positions separated from the rotating axis X, and the distances from the rotating axis X in the concave portions 67 and the concave portions 68 are different.

FIG. 9 is a modified example similar to FIG. 8. A bracket 71 and a click washer 72 are shown in FIG. 9. Two arm portions 73, 74 are arranged in the click washer 72. The arm portion 73 and the arm portion 74 are perpendicularly arranged. The lengths of the arm portion 73 and the arm portion 74 are different from each other, and the arm portion 73 is longer. A convex portion 75 of the arm portion 73 is located far from the rotating axis X in comparison with a convex portion 76 of the arm portion 74. In accordance with this construction, the distances from the rotating axis X in concave portions 77, 78 are different from each other in the bracket 71.

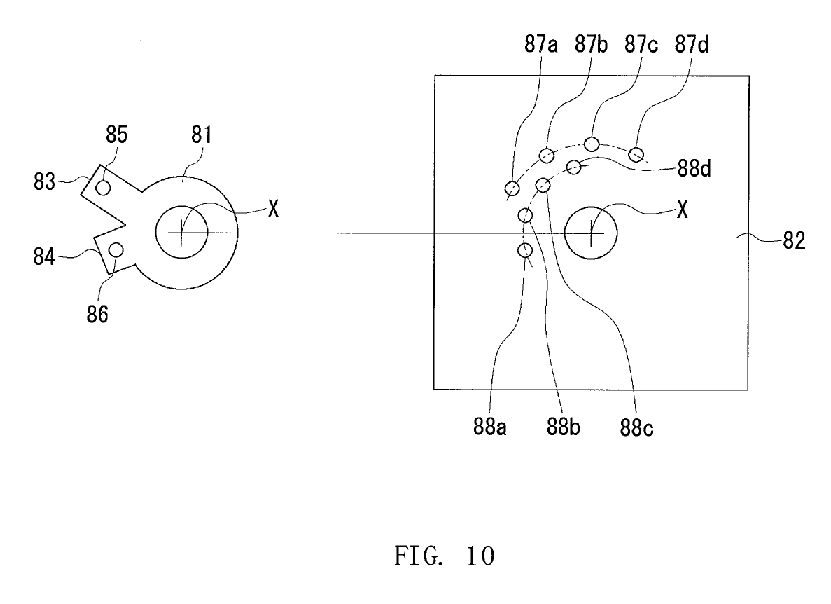

In the above constructions, the radial positions of plural convex portions (distances from the center of rotation) are differently set. This construction is advantageous when the lock of plural stages (multi-angle lock) is realized in a small space as explained below. FIG. 10 is a typical view of a click washer 81 and a bracket 82. In FIG. 10, the click washer 81 also has two arms 83, 84 of different lengths, and the arms 83, 84 have convex portions 85, 86. The distances from the rotating axis X in the convex portions 85, 86 are different from each other.

In FIG. 10, the bracket 82 has two concave portion series (or rows). The two concave portion series are four concave portions 87a to 87d and four concave portions 88a to 88d. The concave portions 87a to 87d correspond to the convex portion 85, and the concave portions 88a to 88d correspond to the convex portion 86. Accordingly, the distances of the concave portions 87a to 87d from the rotating axis X are greater than the distances of the concave portions 88a to 88d from the rotating axis X. Further, in the concave portions 87a to 87d and the concave portions 88a to 88d, the angles between the concave portions with the rotating axis X as a center are the same. The angles (intervals) between the concave portions are narrowly set.

In this embodiment, as shown in FIG. 10, the series of the concave portions 87a to 87d and the series of the concave portions 88a to 88d are partially overlapped. The concave portion 88c is located on the radial inside between the concave portions 87a and 87b. Similarly, the concave portion 88d is located on the radial inside between the concave portions 87b and 87c. Thus, the plural concave portions are arranged in a small space.

In the above construction, when the click washer 81 is rotated together with the display, the convex portions 85, 86 are engaged with the concave portions 87a, 88a, and are subsequently engaged with the concave portions 87b, 88b. Thus, the convex portions 85, 86 perform the engagement in four places, and the display is locked.

As mentioned above, in the construction of FIG. 10, the radii (radial positions) of the convex portions 85, 86 are different, and the radii of the concave portion series for the multi-angle lock are different. Thus, the concave portion series can be overlapped, and the concave portion interval can be reduced. The simultaneous engagement of plural places is realized and the multi-angle lock is realized in a small space.

As mentioned above, the display device in accordance with this embodiment has been explained. In accordance with this embodiment, the engaging portion is constructed so as to perform the engagement in plural engaging places when the display is rotated to the using position. In this embodiment, it is possible to reduce the load to the engaging place for obtaining the same holding force. Accordingly, the load in the engaging place can be reduced, and durability of the engaging portion can be improved.

Further, in this embodiment, the GND force is improved by increasing the engaging portions, and electric performance can be improved.

Further, in this embodiment, the bracket and the click washer respectively correspond to the fixing member and the rotating member. The engaging portion has the fixing member and the rotating member. One of the fixing member and the rotating member has plural convex portions, and the other has plural concave portions. The plural convex portions and the plural concave portions are arranged so as to be engaged. Accordingly, the load to the concave portion and wearing due to this load are reduced by arranging the plural convex portions, and durability of the engaging portion can be improved.

Further, in this embodiment, the plural concave portions arranged so as to be separated in the circumferential direction are provided corresponding to each of the convex portions. Thus, a phase difference is formed and the display can be used in plural using positions.

Further, in this embodiment, with respect to the positions of the plural convex portions, the distances from the center of rotation of the rotating member are different. Thus, as explained with reference to FIG. 10, the construction able to use the display in the plural using positions can be provided with a small space in this embodiment.

Further, in this embodiment, the display device 1 is constructed so as to be mounted to the ceiling of a vehicle. The screen of the display 3 is directed to the ceiling in the storing position, and the display 3 hangs down from the ceiling in the using position. In such a ceiling mounting type display device, the display 3 is opened and closed at the using time and a use terminating time. Further, the display 3 is also opened and closed when it is intended so as not to obstruct the view field of a driver at a backward advancing time of the vehicle. Accordingly, the number of opening and closing times of the display 3 is necessarily increased. In this embodiment, the display device 1 is the ceiling mounting type display device. In the display device mounted to the ceiling, durability of the engaging portion is improved and GND ability can be improved.

Persons of ordinary skill in the art will realize that many modifications and variations of the above embodiments may be made without departing from the novel and advantageous features of the present invention. Accordingly, all such modifications and variations are intended to be included within the scope of the appended claims. The specification and examples are only exemplary. The following claims define the true scope and spirit of the invention.

What is claimed is:

1. A display device comprising:
a display;
a support portion for rotatably supporting said display; and
at least one engaging portion for performing engagement when said display is rotated to a predetermined using position, said engaging portion being constructed so as to perform the engagement in a plurality of engaging places when said display is rotated to said predetermined using position;
wherein said engaging portion has a stationary member and a rotating member rotated in accordance with the rotation of said display, and one of said stationary member and said rotating member has a plurality of convex portions, and the other has a plurality of concave portions, and said plurality of convex portions and said plurality of concave portions are arranged so as to be engaged with each other;
wherein the plurality of concave portions arranged so as to be separated in the circumferential direction are provided corresponding to each of the convex portions in said engaging portion;
wherein the positions of said plurality of convex portions in said engaging portion are set to positions in which the distances from the center of rotation of said rotating member are different from each other.

2. The display device according to claim 1, wherein said rotating member has said plurality of convex portions, and said stationary member includes a plurality of concave portion rows, each of said plurality of concave portion rows including said plurality of concave portions arranged so as to be separated in the circumferential direction around the center of rotation, and distances to said plurality of concave portion rows from the center of rotation are different from each other in accordance with difference between distances to said plurality of convex portions from the center of rotation, and angles between said concave portions around the center of rotation are the same in said plurality of concave portion rows, and said plurality of concave portion rows are partially overlapped in the circumferential direction.

3. A ceiling mounting type display device having the display device according to claim 1 and mounted to a ceiling.
